(19) United States
(12) Patent Application Publication
(10) Pub. No.: US 2025/0174554 A1
(43) Pub. Date: May 29, 2025

(54) INTEGRATED CIRCUIT DEVICES HAVING ENHANCED WIRING STRUCTURES THEREIN

(71) Applicant: Samsung Electronics Co., Ltd., Suwon-si (KR)

(72) Inventors: Seung Yong Yoo, Suwon-si (KR); Eun-Ji Jung, Suwon-si (KR); Rak Hwan Kim, Suwon-si (KR); Seung Keun Cha, Suwon-si (KR)

(21) Appl. No.: 18/767,199

(22) Filed: Jul. 9, 2024

(30) Foreign Application Priority Data
Nov. 28, 2023 (KR) 10-2023-0168016

(51) Int. Cl. H01L 23/528; H01L 23/532

(52) U.S. Cl. CPC H01L 23/5283; H01L 23/528; H01L 23/53266

(57) ABSTRACT

A semiconductor device includes a lower wiring structure that extends within a lower interlayer insulating film; the lower wiring structure contains a lower barrier film and a lower filling film. An upper interlayer insulating film is provided, which extends on the lower interlayer insulating film; the upper interlayer insulating film has an upper wiring trench therein. An upper wiring structure is provided that extends within the upper wiring trench and is electrically connected to the lower wiring structure; the upper wiring structure includes an upper barrier film, an upper filling film, and an upper capping film extending on the upper filling film. The upper filling film extends on the upper barrier film and is in contact with the upper barrier film, and the upper barrier film includes a sidewall portion extending along a sidewall of the upper wiring trench.

### REFERENCE TO PRIORITY APPLICATION

This application claims priority under 35 U.S.C. 119 to Korean Patent Application No. 10-2023-0168016, filed Nov. 28, 2023, the disclosure of which is hereby incorporated herein by reference.

### BACKGROUND

The present disclosure relates to integrated circuit devices and, more particularly, to integrated circuit devices having wiring structures therein, which are formed during back-end-of-line (BEOL) processes.

Due to the development of electronic technology, down-scaling of integrated circuit devices has progressed rapidly, thereby requiring higher integration and lower power consumption within an integrated circuit chip. In order to cope with the demand for higher integration and lower power consumption, a feature size of semiconductor devices within an integrated circuit continues to decrease; as the feature size of semiconductor devices decreases, various studies are being conducted on stable electrical connection schemes between wirings within the integrated circuit.

### SUMMARY

A purpose of the present disclosure is to provide integrated circuit devices having improved element performance and reliability and connectivity to semiconductor devices therein.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to an aspect of the present disclosure, there is provided a semiconductor device having a lower wiring structure therein, which is disposed within a lower interlayer insulating film, and includes a lower barrier film and a lower filling film. An upper interlayer insulating film is provided, which extends on the lower interlayer insulating film, and includes an upper wiring trench and an upper wiring structure extending within the upper wiring trench and electrically connected to the lower wiring structure. The upper wiring structure includes an upper barrier film, an upper filling film, and an upper capping film extending on the upper filling film. The upper filling film extends on the upper barrier film and is in electrical contact with the upper barrier film; the upper barrier film includes a sidewall portion extending along a sidewall of the upper wiring trench, and the sidewall portion of the upper barrier film includes tantalum nitride doped with manganese (Mn).

According to an aspect of the present disclosure, there is provided a semiconductor device including a lower wiring structure extending within a lower interlayer insulating film and including a lower barrier film and a lower filling film. An upper interlayer insulating film is provided on the lower interlayer insulating film and includes an upper wiring trench and an upper wiring structure extending within the upper wiring trench, and is electrically connected to the lower wiring structure. The upper wiring structure includes an upper barrier film, an upper filling film, and an upper liner between the upper barrier film and the upper filling film. The upper barrier film may include tantalum nitride, and the upper liner may extend along a sidewall of the upper wiring trench, but not extend along a lower surface of the upper wiring trench. In some embodiments, the upper liner may include manganese (Mn).

According to a further aspect of the present disclosure, there is provided a semiconductor device including a lower wiring structure extending within a lower interlayer insulating film and including a lower barrier film, a lower filling film, and a lower capping film. The lower filling film is in contact with the lower barrier film and the lower capping film. An upper interlayer insulating film extends on the lower interlayer insulating film, and includes an upper wiring trench and an upper wiring structure extending within the upper wiring trench, and is electrically connected to the lower wiring structure. The upper wiring structure may include an upper barrier film, an upper filling film, and an upper capping film extending on the upper filling film. The upper filling film extends on the upper barrier film and is in contact with the upper barrier film and the upper capping film. The upper barrier film includes a sidewall portion extending along a sidewall of the upper wiring trench and a bottom portion extending along a lower surface of the upper wiring trench. Each of the sidewall portion of the upper barrier film and the lower barrier film includes tantalum nitride doped with manganese (Mn). In addition, the bottom portion of the upper barrier film may include manganese. According to further embodiments, each of the upper capping film and the lower capping film includes cobalt (Co), wherein each of the upper filling film and the lower filling film includes copper (Cu).

Specific details of other embodiments are included in the detailed description and drawings. However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail some embodiments thereof with reference to the attached drawings, in which:

FIG. 1 is an example layout diagram for illustrating a semiconductor device according to some embodiments.

FIG. 2 is an illustrative cross-sectional view taken along a line A-A in FIG. 1.

FIG. 3 is an illustrative cross-sectional view taken along a line B-B in FIG. 1.

FIG. 4 is an enlarged view of a P portion of FIG. 2.

FIG. 5 is an enlarged view of a Q portion of FIG. 3.

FIG. 6 is a table for describing a metal that may be detected in LINE1 and LINE2 in FIG. 4.

FIG. 7 and FIG. 8 are diagrams for illustrating a semiconductor device according to some embodiments.

FIG. 9 is a diagram for illustrating a semiconductor device according to some embodiments.

FIG. 10 and FIG. 11 are diagrams for illustrating a semiconductor device according to some embodiments.

FIG. 12 and FIG. 13 are diagrams for illustrating a semiconductor device according to some embodiments.

FIG. 14 and FIG. 15 are diagrams for illustrating a semiconductor device according to some embodiments.

FIG. 16 to FIG. 19 are diagrams for illustrating a semiconductor device according to some embodiments.

FIG. 20 and FIG. 21 are diagrams for illustrating a semiconductor device according to some embodiments.

FIG. 22 and FIG. 23 are diagrams for illustrating a semiconductor device according to some embodiments.

FIG. 24 and FIG. 25 are diagrams for illustrating a semiconductor device according to some embodiments.

FIG. 26 is a diagram for illustrating a semiconductor device according to some embodiments.

FIG. 27 is a diagram for illustrating a semiconductor device according to some embodiments.

FIG. 28 to FIG. 30 are diagrams for illustrating a semiconductor device according to some embodiments.

FIG. 31 to FIG. 36 are diagrams of intermediate structures corresponding to intermediate steps for illustrating a method for manufacturing a semiconductor device according to some embodiments.

FIG. 37 and FIG. 38 are diagrams of intermediate structures corresponding to intermediate steps for illustrating a method for manufacturing a semiconductor device according to some embodiments.

### DETAILED DESCRIPTION OF EMBODIMENTS

Advantages and features of the present disclosure, and a method of achieving the advantages and features will become apparent with reference to embodiments described later in detail together with the accompanying drawings. However, an embodiment of embodiments of the present disclosure are not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and an embodiment of embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers.

It will be understood that when an element or layer is referred to as being “connected to”, or “coupled to” another element or layer, it may be directly connected to or coupled to another element or layer, or one or more intervening elements or layers therebetween may be present. In addition, it will also be understood that when an element or layer is referred to as being “between” two elements or layers, it may be the only element or layer between the two elements or layers, or one or more intervening elements or layers therebetween may also be present.

In addition, it will also be understood that when an element or layer is referred to as being “between” two elements or layers, it may be the only element or layer between the two elements or layers, or one or more intervening elements or layers therebetween may also be present. Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be implemented independently of each other and may be implemented together in an association relationship. In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, embodiments of the present disclosure are described in detail with reference to the attached drawings.

In drawings of a semiconductor device according to some embodiments, a fin-type transistor (FinFET) including a channel area having a shape of a fin-type pattern, a transistor including a nanowire or nanosheet, and a multi-bridge channel field effect transistor (MBCFET™), or a vertical transistor (Vertical FET) is shown by way of example. However, embodiments of the present disclosure are not limited thereto. n another example, the semiconductor device according to some embodiments may include a tunneling transistor (tunneling FET) or a three-dimensional (3D) transistor. In still another example, the semiconductor device according to some embodiments may include a planar transistor. In addition, the technical idea of the present disclosure may be applied to a 2D material based transistor (a 2D material based FET) and a heterostructure thereof. Furthermore, the semiconductor device according to some embodiments may include a bipolar junction transistor, a lateral double MOS (LDMOS), or etc.

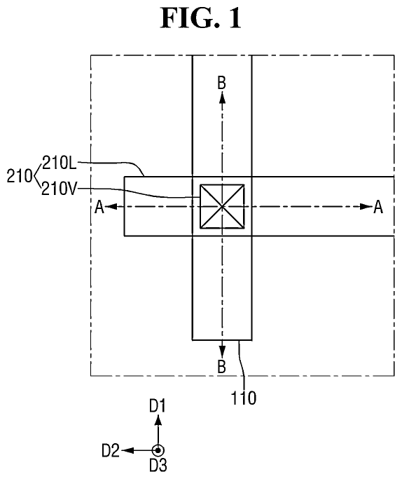

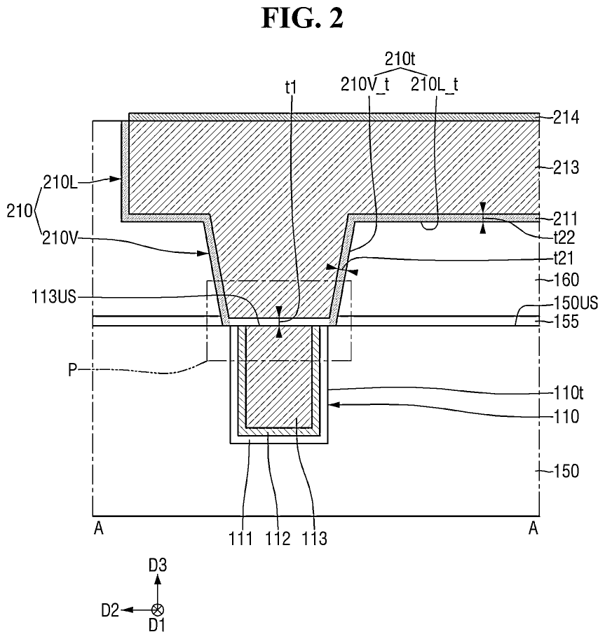

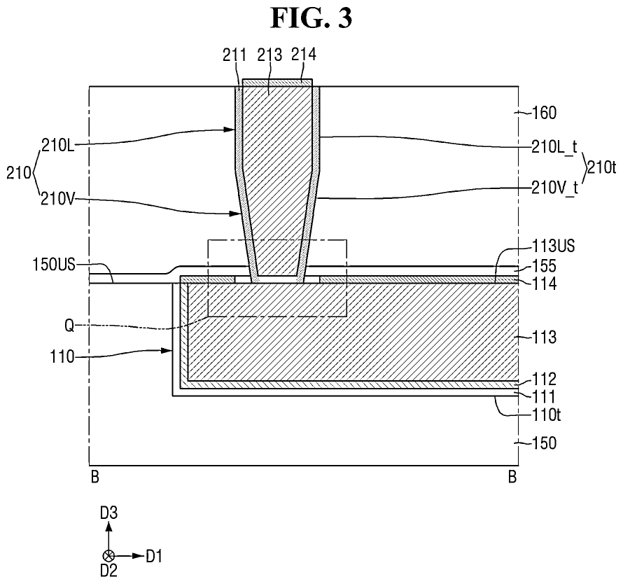

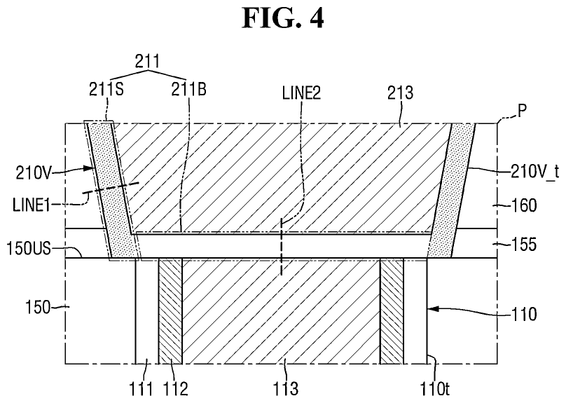

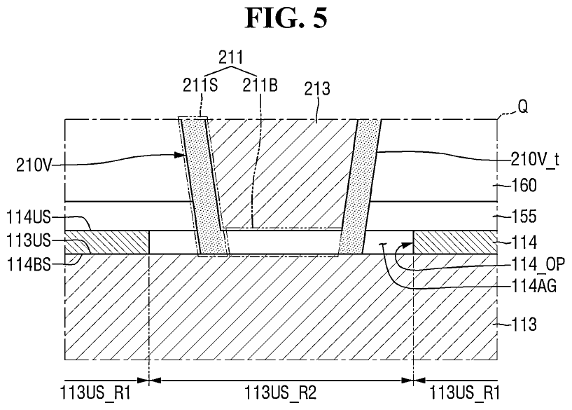

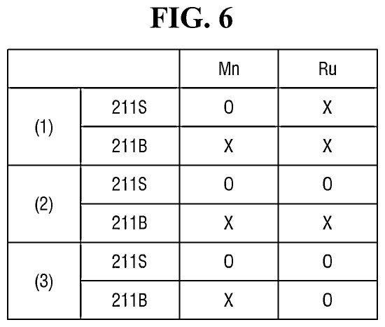

FIG. 1 is an example layout diagram for illustrating a semiconductor device according to some embodiments. FIG. 2 is an illustrative cross-sectional view taken along a line A-A in FIG. 1. FIG. 3 is an illustrative cross-sectional view taken along a line B-B in FIG. 1. FIG. 4 is an enlarged view of a P portion of FIG. 2. FIG. 5 is an enlarged view of a Q portion of FIG. 3. FIG. 6 is a table for describing a metal that may be detected in LINE1 and LINE2 in FIG. 4.

Referring to FIG. 1 to FIG. 6, the semiconductor device according to some embodiments may include a lower wiring structure 110 and an upper wiring structure 210. The lower wiring structure 110 may be disposed within the first interlayer insulating film 150, and may extend in an elongate manner in a first direction D1. The lower wiring structure 110 may have a line shape extending in the first direction D1. For example, the first direction D1 may be a length direction of the lower wiring structure 110, and a second direction D2 may a width direction of the lower wiring structure 110. In this regard, the first direction D1 intersects the second direction D2 and a third direction D3. The second direction D2 intersects the third direction D3.

A first interlayer insulating film 150 may cover a gate electrode and a source/drain of a transistor formed in a front-end-of-line (FEOL) process. Alternatively, the first interlayer insulating film 150 may be an interlayer insulating film formed in a back-end-of-line (BEOL) process. In other words, in one example, the lower wiring structure 110 may be a contact or contact wiring formed in a middle-of-line (MOL) process. In another example, the lower wiring structure 110 may be connection wiring formed in a back-end-of-line (BEOL) process. In following descriptions, an example in which the lower wiring structure 110 is the connection wiring formed in the BEOL process is described.

For example, the first interlayer insulating film 150 may include at least one of silicon oxide, silicon nitride, silicon oxynitride, and a low dielectric constant material. The low dielectric constant material may be, for example, silicon oxide having carbon and hydrogen at moderately high contents, for example, SiCOH. When carbon is contained in an insulating material, a dielectric constant of the insulating material may be lowered. However, to further lower the dielectric constant of the insulating material, the insulating material may contain pores, such as gas-filled or air-filled cavities.

The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SILK, amorphous fluorinated carbon, silica aerogels, silica xerogels, mesoporous silica, or combinations thereof. However, the spirit of embodiments of the present disclosure are not limited thereto.

The lower wiring structure 110 may be disposed at a first metal level. The first interlayer insulating film 150 may include a lower wiring trench 110t extending in an elongate manner in the first direction D1. The lower wiring structure 110 may be disposed within the first interlayer insulating film 150. The lower wiring structure 110 may be disposed within the lower wiring trench 110t. The lower wiring structure 110 fills the lower wiring trench 110t.

The lower wiring structure 110 may include a lower barrier film 111, a lower liner 112, a lower filling film 113, and a lower capping film 114. The lower barrier film 111 may extend along a sidewall and a lower surface of the lower wiring trench 110t. The lower liner 112 may be disposed on the lower barrier film 111. The lower liner 112 may extend along the sidewall and the lower surface of the lower wiring trench 110t while being disposed on the lower barrier film 111. The lower filling film 113 is disposed on the lower liner 112. The lower filling film 113 may fill the remainder of the lower wiring trench 110t. The lower capping film 114 may be disposed on an upper surface 113US of the lower filling film. The lower capping film 114 may extend along the upper surface 113US of the lower filling film. The lower capping film 114 may be disposed on an upper surface of the lower liner 112. Unlike what is shown, the lower capping film 114 need not cover the upper surface of the lower liner 112.

The lower capping film 114 may include an upper surface 114US and a lower surface 114BS that are opposite to each other in the third direction D3. The lower surface 114BS of the lower capping film faces the upper surface 113US of the lower filling film. The lower surface 114BS of the lower capping film may contact the upper surface 113US of the lower filling film.

The upper surface 113US of the lower filling film may include a first area 113US_R1 and a second area 113US_R2. The first area 113US_R1 of the upper surface of the lower filling film is an area covered with the lower capping film 114. The first area 113US_R1 of the upper surface of the lower filling film may be in contact with the lower capping film 114.

The second area 113US_R2 of the upper surface of the lower filling film is an area not covered with the lower capping film 114. The second area 113US_R2 of the upper surface of the lower filling film may not be in contact with the lower capping film 114.

In other words, the lower capping film 114 may include a capping opening 114_OP that exposes a portion of the upper surface 113US of the lower filling film. The second area 113US_R2 of the upper surface of the lower filling film may be exposed through the capping opening 114_OP.

When the lower liner 112 and the lower capping film 114 are made of the same material, the upper surface of the lower liner 112 may not be distinguished at a boundary between the lower liner 112 and the lower capping film 114. The lower capping film 114 may not cover the upper surface of the lower barrier film 111. Unlike what is shown, the lower capping film 114 may cover at least a portion of the upper surface of the lower barrier film 111.

The upper surface of the lower liner 112 is shown to be coplanar with the upper surface of the lower filling film 113US and the upper surface of the lower barrier film 111. However, embodiments of the present disclosure are not limited thereto. In this regard, the upper surface of the lower liner 112 may mean the uppermost surface of a portion of the lower liner 112 extending along the sidewall of the lower wiring trench 110t. The lower barrier film 111 may include a conductive material, for example, metal nitride. The lower barrier film 111 may include, for example, at least one of tantalum nitride (TaN), titanium nitride (TiN), tungsten nitride (WN), zirconium nitride (ZrN), vanadium nitride (VN), and niobium nitride (NbN). In one example, the lower barrier film 111 may include tantalum nitride (TaN). In another example, the lower barrier film 111 may include tantalum nitride doped with ruthenium (Ru). In the semiconductor device according to some embodiments, the lower barrier film 111 may not include manganese (Mn). The lower barrier film 111 may not include doped manganese (Mn).

The lower liner 112 may include a conductive material, for example, a metal. The lower liner 112 may include, for example, cobalt (Co) or ruthenium-doped cobalt.

In the semiconductor device according to some embodiments, the lower liner 112 may be made of cobalt (Co). For example, the lower liner 112 may be made of cobalt. In this regard, a “cobalt film” may be a film made only of cobalt, or may be a film containing impurities introduced during a process of forming the cobalt film.

The lower filling film 113 may include a conductive material, for example, at least one of aluminun (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB₂, MoB₂, TaB₂, V₂AlC, and CrAlC. In the semiconductor device according to some embodiments, the lower filling film 113 may include copper (Cu).

The lower capping film 114 may include a conductive material, for example, a metal. The lower capping film 114 may include, for example, cobalt (Co). In the semiconductor device according to some embodiments, the lower capping film 114 may be made of cobalt (Co).

Unlike what is shown, the lower wiring structure 110 may have a single film structure. Although not shown, a via pattern connecting conductive patterns disposed under the lower wiring structure 110 to each other may be further included in the semiconductor device. The lower wiring structure 110 may be formed, for example, using a damascene method. In FIG. 2, a width of the lower wiring structure 110 in the second direction D2 is shown to be constant. However, embodiments of the present disclosure are not limited thereto. Unlike what is shown, the width of the lower wiring structure 110 in the second direction D2 may decrease as the lower wiring structure 110 extends away from the upper surface 150US of the first interlayer insulating film.

A first etch stop film 155 may be disposed on the lower wiring structure 110 and the first interlayer insulating film 150. The first etch stop film 155 may contact the upper surface 150US of the first interlayer insulating film and the upper surface 114US of the lower capping film.

In the semiconductor device according to some embodiments, the lower capping film 114 may be partially undercut under the first etch stop film 155. In other words, the first etch stop film 155 may cover a portion of the second area 113US_R2 of the upper surface of the lower filling film. The first etch stop film 155 may overlap the portion of the second area 113US_R2 of the upper surface of the lower filling film in the third direction D3.

For example, a capping air gap 114AG may be disposed in an area where the lower capping film 114 is undercut. The capping air gap 114AG may be disposed between the first etch stop film 155 and the lower filling film 113. Unlike what is shown, in one example, at least a portion of the area where the lower capping film 114 is undercut may be filled with an insulating material. In another example, the lower capping film 114 may not be undercut under the first etch stop film 155.

A second interlayer insulating film 160 may be disposed on the first etch stop film 155. The first etch stop film 155 may be disposed between the first interlayer insulating film 150 and the second interlayer insulating film 160. The second interlayer insulating film 160 may include an upper wiring trench 210t. The upper wiring trench 210t may extend through the first etch stop film 155. The upper wiring trench 210t exposes a portion of the lower wiring structure 110.

The upper wiring trench 210t may extend through the lower capping film 114. The upper wiring trench 210t may expose a portion of the upper surface 113US of the lower filling film. The upper wiring trench 210t may include an upper via trench 210V_t and an upper wiring line trench 210L_t. The upper wiring line trench 210L_t may extend in an elongate manner in the second direction D2. The upper wiring line trench 210L_t may extend to an upper surface of the second interlayer insulating film 160. The upper via trench 210V_t may be formed on a lower surface of the upper wiring line trench 210L_t.

For example, a lower surface of the upper wiring trench 210t may be a lower surface of the upper via trench 210V_t. In the semiconductor device according to some embodiments, the lower surface of the upper wiring trench 210t may be defined by the upper surface 113US of the lower filling film. For example, the lower surface of the upper wiring trench 210t may be defined by at least a portion of the second area 113US_R2 of the upper surface of the lower filling film.

A sidewall of the upper wiring trench 210t may include a sidewall and the lower surface of the upper wiring line trench 210L_t and a sidewall of the upper via trench 210V_t. The sidewall and the lower surface of the upper wiring line trench 210L_t may be defined by the second interlayer insulating film 160. The sidewall of the upper via trench 210V_t may be defined by the second interlayer insulating film 160 and the first etch stop film 155. The second interlayer insulating film 160 may include, for example, at least one of silicon oxide, silicon nitride, silicon oxynitride, and a low dielectric constant material.

The first etch stop film 155 may include a material having an etch selectivity with respect to a material of the second interlayer insulating film 160. The first etch stop film 155 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), aluminum oxycarbide (AlOC), and combinations thereof. The first etch stop film 155 is shown as a single film. However, this is only for convenience of illustration and embodiments of the present disclosure are not limited thereto. In another example, unlike what is shown, the first etch stop film 155 may include a plurality of insulating films sequentially stacked on the first interlayer insulating film 150.

An upper wiring structure 210 may be disposed within the upper wiring trench 210t. The upper wiring structure 210 may fill the upper wiring trench 210t. The upper wiring structure 210 may be disposed within the second interlayer insulating film 160.

The upper wiring structure 210 is disposed on the lower wiring structure 110. The upper wiring structure 210 is connected to the lower wiring structure 110. The upper wiring structure 210 is in contact with the lower wiring structure 110. In the semiconductor device according to some embodiments, the upper wiring structure 210 may contact the lower filling film 113. For example, the upper wiring structure 210 may contact the second area 113US_R2 of the upper surface of the lower filling film.

The upper wiring structure 210 includes an upper wiring line 210L and an upper via 210V. The upper via 210V connects the upper wiring line 210L and the lower wiring structure 110 to each other. The upper via 210V may contact the lower filling film 113. The upper via 210V may contact the second area 113US_R2 of the upper surface of the lower filling film. The upper via 210V may extend through the capping opening 114_OP and contact the lower filling film 113.

When etching a portion of the lower capping film 114 to expose the second area 113US_R2 of the upper surface of the lower filling film, the lower filling film 113 may not be removed by the etching process. The first area 113US_R1 of the upper surface of the lower filling film may be coplanar with the second area 113US_R2 of the upper surface of the lower filling film. In the cross-sectional view of FIG. 3, the upper surface 113US of the lower filling film in contact with the upper wiring structure 210 may be flat.

Unlike what is shown, the upper surface 113US of the lower filling film in contact with the upper wiring structure 210 may have a concave curved shape. At least the portion of the second area 113US_R2 of the upper surface of the lower filling film may have a concave curved shape. The upper wiring structure 210 fills the upper via trench 210V_t and upper wiring line trench 210L_t. The upper wiring line 210L is disposed within the upper wiring line trench 210L_t. The upper via 210V is disposed within the upper via trench 210V_t. The upper wiring line 210L is disposed at a second metal level, which is different from the first metal level. The upper wiring line 210L is disposed at the second metal level, which is higher than the first metal level. The upper wiring structure 210 may include an upper barrier film 211, an upper filling film 213, and an upper capping film 214.

The upper barrier film 211 may extend along the sidewall and the lower surface of the upper wiring trench 210t. The upper barrier film 211 may extend along the sidewall and the lower surface of the upper wiring line trench 210L_t and the sidewall and the lower surface of the upper via trench 210V_t. The upper barrier film 211 may include a sidewall portion 211S and a bottom portion 211B. The sidewall portion 211S of the upper barrier film may extend along the sidewall of the upper wiring trench 210t. The bottom portion 211B of the upper barrier film may extend along the lower surface of the upper wiring trench 210t.

The sidewall portion 211S of the upper barrier film may extend along the sidewall and the lower surface of the upper wiring line trench 210L_t and the sidewall of the upper via trench 210V_t. The bottom portion 211B of the upper barrier film may extend along the lower surface of the upper via trench 210V_t. For example, the bottom portion 211B of the upper barrier film may contact the upper surface 113US of the lower filling film that defines the lower surface of the upper via trench 210V_t. The upper barrier film 211 may not cover an entirety of a portion of the lower wiring structure 110 exposed through the upper via trench 210V_t. In the cross-sectional view, the bottom portion 211B of the upper barrier film may not be in contact with an entirety of the second area 113US_R2 of the upper surface of the lower filling film. Unlike what is shown, in the cross-sectional view, the bottom portion 211B of the upper barrier film may cover an entirety of the second area 113US_R2 of the upper surface of the lower filling film.

A thickness t21 and t22 of the sidewall portion 211S of the upper barrier film may be equal to a thickness t1 of the bottom portion 211B of the upper barrier film. The thickness t21 of a portion of the sidewall portion 211S of the upper barrier film on the sidewall of the upper via trench 210V_t may be equal to the thickness t1 of a portion of the sidewall portion 211S of the upper barrier film on the lower surface of the upper via trench 210V_t. The thickness t21 of a portion of the sidewall portion 211S of the upper barrier film on the sidewall of the upper via trench 210V_t may be equal to the thickness t22 of a portion of the sidewall portion 211S of the upper barrier film on the lower surface of the upper wiring line trench 210L_t.

The upper barrier film 211 may include a conductive material, for example, metal nitride. In the semiconductor device according to some embodiments, the upper barrier film 211 may include tantalum nitride (TaN) doped with manganese (Mn). For example, a portion of the upper barrier film 211 may include tantalum nitride (TaN) doped with manganese (Mn), and the remainder of the upper barrier film 211 may include tantalum nitride (TaN) that is not doped with manganese (Mn).

In FIG. 4 to FIG. 6, the sidewall portion 211S of the upper barrier film may include manganese-doped tantalum nitride (TaN). The sidewall portion 211S of the upper barrier film may include tantalum nitride (TaN), and manganese (Mn)-doped tantalum nitride (TaN). The bottom portion 211B of the upper barrier film may include tantalum nitride (TaN). The bottom portion 211B of the upper barrier film may not include manganese (Mn). Manganese (Mn) may not be doped into the bottom portion 211B of the upper barrier film. The bottom portion 211B of the upper barrier film may not include manganese-doped tantalum nitride (TaN). The sidewall portion 211S of the upper barrier film may not include tantalum nitride that is not doped with manganese.

In one example ((1) in FIG. 6), each of the sidewall portion 211S of the upper barrier film and the bottom portion 211B of the upper barrier film may not contain doped ruthenium (Ru). For example, the sidewall portion 211S of the upper barrier film may be made of tantalum nitride (TaN) doped with manganese. The bottom portion 211B of the upper barrier film may be made of tantalum nitride (TaN).

In another example ((2) in FIG. 6), the sidewall portion 211S of the upper barrier film may further include doped ruthenium (Ru). The sidewall portion 211S of the upper barrier film may include tantalum nitride (TaN) doped with manganese (Mn) and ruthenium (Ru). For example, the sidewall portion 211S of the upper barrier film may be made of tantalum nitride (TaN) doped with manganese (Mn) and ruthenium (Ru). The bottom portion 211B of the upper barrier film may not contain doped ruthenium (Ru). For example, the bottom portion 211B of the upper barrier film may be made of tantalum nitride (TaN).

In still another example ((3) in FIG. 6), the sidewall portion 211S of the upper barrier film and the bottom portion 211B of the upper barrier film may further include doped ruthenium (Ru). The sidewall portion 211S of the upper barrier film may include tantalum nitride (TaN) doped with manganese (Mn) and ruthenium (Ru). The bottom portion 211B of the upper barrier film may include tantalum nitride (TaN) doped with ruthenium (Ru). For example, the sidewall portion 211S of the upper barrier film may be made of tantalum nitride (TaN) doped with manganese (Mn) and ruthenium (Ru). The bottom portion 211B of the upper barrier film may be made of tantalum nitride (TaN) doped with ruthenium (Ru).

The upper filling film 213 may be disposed on the upper barrier film 211. For example, the upper filling film 213 may contact the upper barrier film 211. The upper filling film 213 may fill the remainder of the upper wiring trench 210t. Because the upper barrier film 211 is disposed between the upper filling film 213 and the lower wiring structure 110, the upper filling film 213 may not contact the lower wiring structure 110. The upper filling film 213 may contain a conductive material, for example, copper (Cu).

The upper capping film 214 may be disposed on the upper filling film 213. The upper capping film 214 may extend along an upper surface of the upper filling film 213. The upper capping film 214 may contact the upper surface of the upper filling film 213. The upper capping film 214 may not be disposed on the upper surface of the upper barrier film 211. Unlike what is shown, the upper capping film 214 may cover the upper surface of the upper barrier film 211. The upper capping film 214 may include a conductive material, for example, a metal. The upper capping film 214 may include, for example, cobalt (Co). In the semiconductor device according to some embodiments, the upper capping film 214 may be made of cobalt (Co). Tantalum nitride (TaN) doped with manganese (Mn) may be present along the sidewall of the upper wiring trench 210t, and thus may prevent the copper included in the upper filling film 213 from diffusing into the second interlayer insulating film 160. Furthermore, the upper capping film 214 may be formed on the upper surface of the upper filling film 213, and thus may prevent the copper included in the upper filling film 213 from diffusing along the upper surface of the second interlayer insulating film 160. Thus, the performance and reliability of the semiconductor device may be improved.

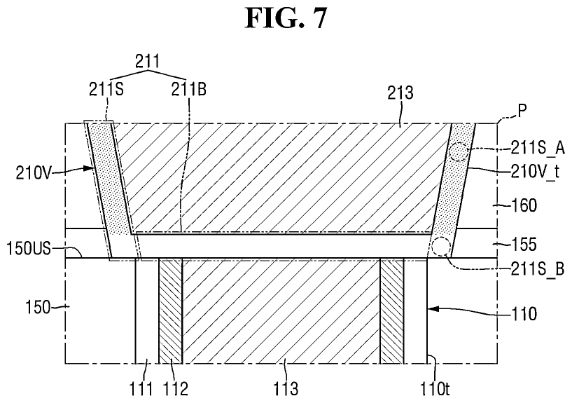

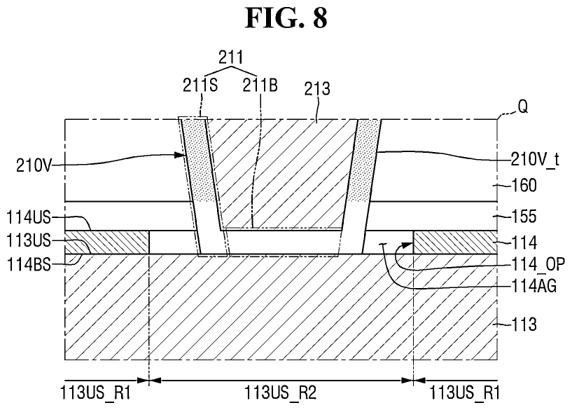

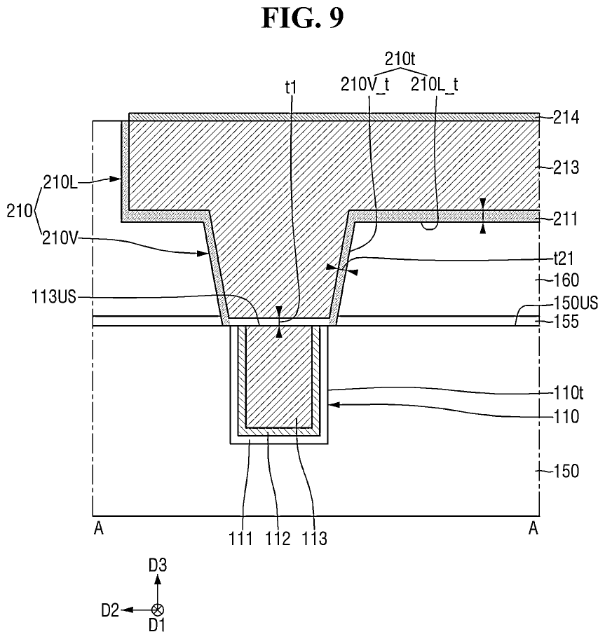

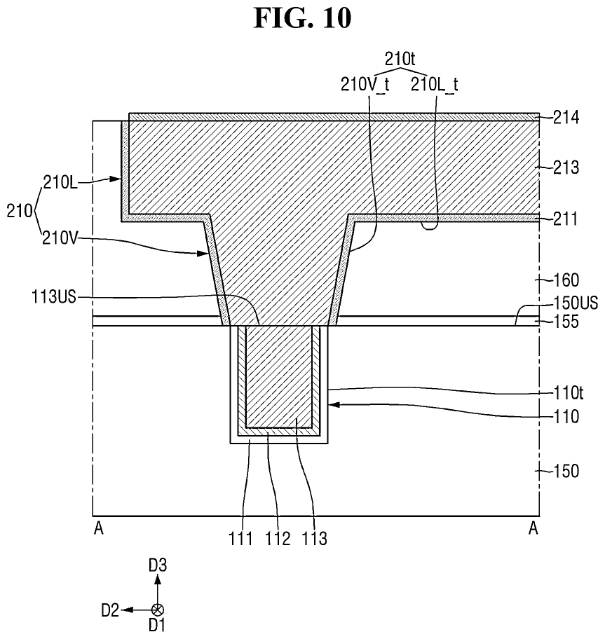

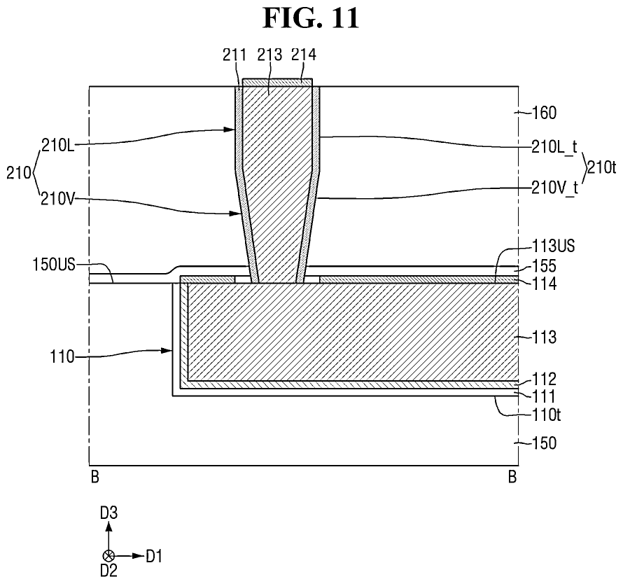

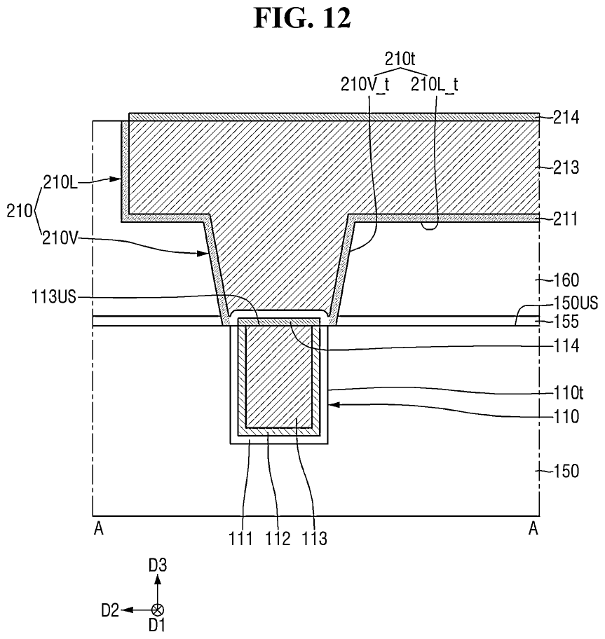

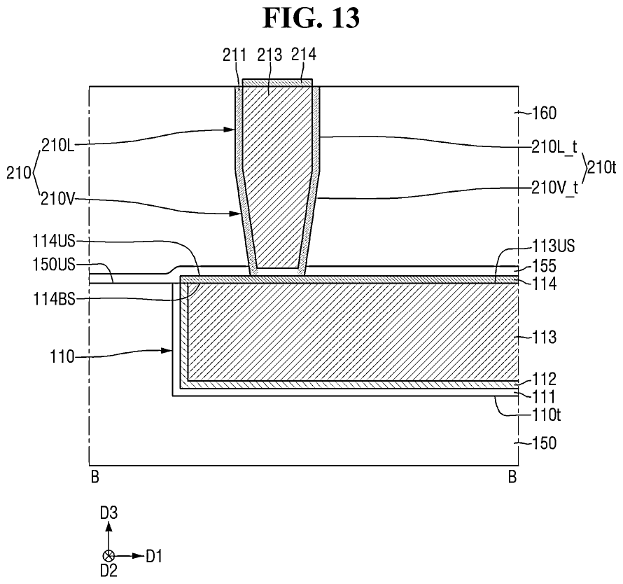

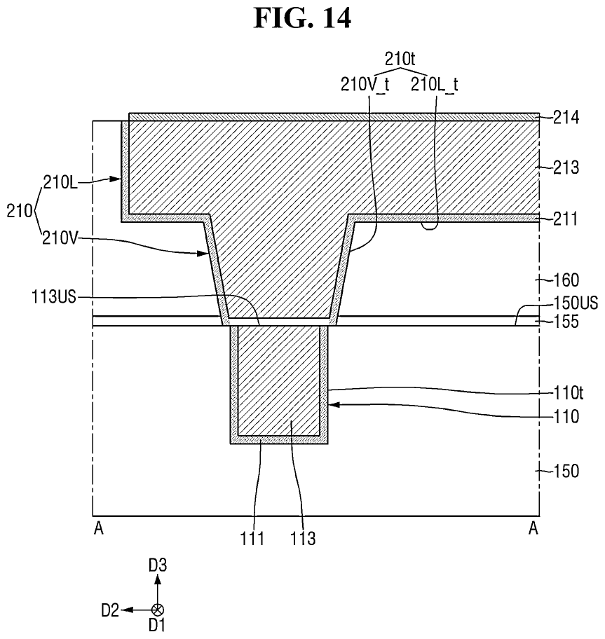

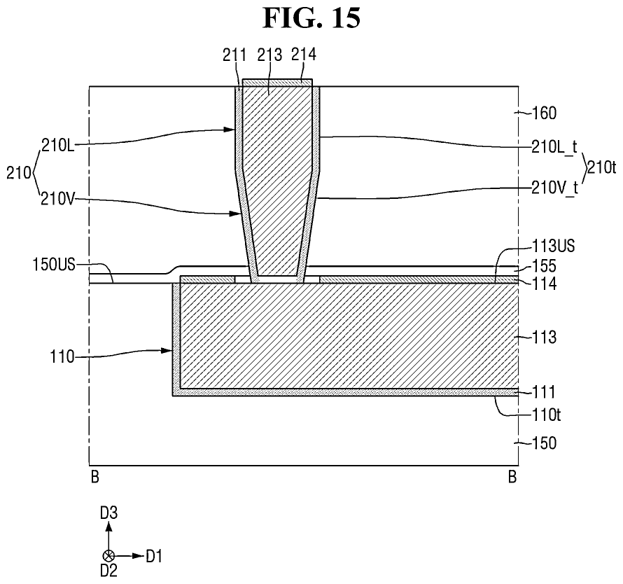

FIG. 7 and FIG. 8 are diagrams for illustrating a semiconductor device according to some embodiments. FIG. 9 is a diagram for illustrating a semiconductor device according to some embodiments. FIG. 10 and FIG. 11 are diagrams for illustrating a semiconductor device according to some embodiments. FIG. 12 and FIG. 13 are diagrams for illustrating a semiconductor device according to some embodiments. FIG. 14 and FIG. 15 are diagrams for illustrating a semiconductor device according to some embodiments. For convenience of description, differences thereof from what have been described above with reference to FIG. 1 to FIG. 6 will be described.

For reference, FIG. 7 is an enlarged view of a P portion of FIG. 2. FIG. 8 is an enlarged view of a Q portion of FIG. 3. Referring to FIG. 7 and FIG. 8, in a semiconductor device according to some embodiments, the sidewall portion 211S of the upper barrier film may include a first portion 211S_A and a second portion 211S_B.

The first portion 211S_A of the sidewall of the upper barrier film may include tantalum nitride (TaN) doped with manganese. For example, the first portion 211S_A of the sidewall of the upper barrier film may be made of manganese-doped tantalum nitride (TaN). The second portion 211S_B of the sidewall of the upper barrier film may not contain manganese. The second portion 211S_B of the sidewall of the upper barrier film may include tantalum nitride (TaN) that is not doped with manganese. For example, the second portion 211S_B of the sidewall of the upper barrier film may be made of tantalum nitride (TaN) that is not doped with manganese. The first portion 211S_A of the sidewall of the upper barrier film is disposed on the second portion 211S_B of the sidewall of the upper barrier film. The first portion 211S_A of the sidewall of the upper barrier film may overlap the second interlayer insulating film 160 in the first direction D1 and/or the second direction D2.

Referring to FIG. 9, in a semiconductor device according to some embodiments, the thickness t22 of the portion of the sidewall portion 211S of the upper barrier film on the lower surface of the upper wiring line trench 210L_t may be greater than the thickness t21 of the portion of the sidewall portion 211S of the upper barrier film on the sidewall of the upper via trench 210V_t. The thickness t22 of the portion of the sidewall portion 211S of the upper barrier film on the lower surface of the upper wiring line trench 210L_t may be greater than the thickness t1 of the portion of the sidewall portion 211S of the upper barrier film on the lower surface of the upper via trench 210V_t. The thickness t21 of the portion of the sidewall portion 211S of the upper barrier film on the sidewall of the upper via trench 210V_t may be equal to the thickness t1 of the portion of the sidewall portion 211S of the upper barrier film on the lower surface of the upper via trench 210V_t. The thickness t21 and t22 of the sidewall portion 211S of the upper barrier film may be equal to or greater than the thickness t1 of the bottom portion 211B of the upper barrier film.

Referring to FIG. 10 and FIG. 11, in a semiconductor device according to some embodiments, the upper barrier film 211 may include the sidewall portion 211S of the upper barrier film and may not include the bottom portion 211B of the upper barrier film. The upper barrier film 211 may not be disposed between the upper filling film 213 and the lower wiring structure 110. The upper filling film 213 may contact the lower wiring structure 110. For example, the upper filling film 213 may contact the upper surface 113US of the lower filling film.

Referring to FIG. 12 and FIG. 13, in a semiconductor device according to some embodiments, the upper barrier film 211 may include a portion extending along the upper surface 114US of the lower capping film. The bottom (211B in FIG. 4) of the upper barrier film may extend along the upper surface 114US of the lower capping film. The upper barrier film 211 may contact the upper surface 114US of the lower capping film. Since a portion of the lower capping film 114 is disposed between the upper barrier film 211 and the lower filling film 113, the upper barrier film 211 may not contact the upper surface 113US of the lower filling film.

Referring to FIGS. 14 and 15, in a semiconductor device according to some embodiments, the lower wiring structure 110 may not include the lower liner (112 in FIGS. 2 and 3). The lower barrier film 111 may be in contact with the lower filling film 113. The lower barrier film 111 may contain doped manganese (Mn). In one example, the lower barrier film 111 may include tantalum nitride (TaN) doped with manganese (Mn). In another example, the lower barrier film 111 may include tantalum nitride doped with manganese (Mn) and ruthenium (Ru).

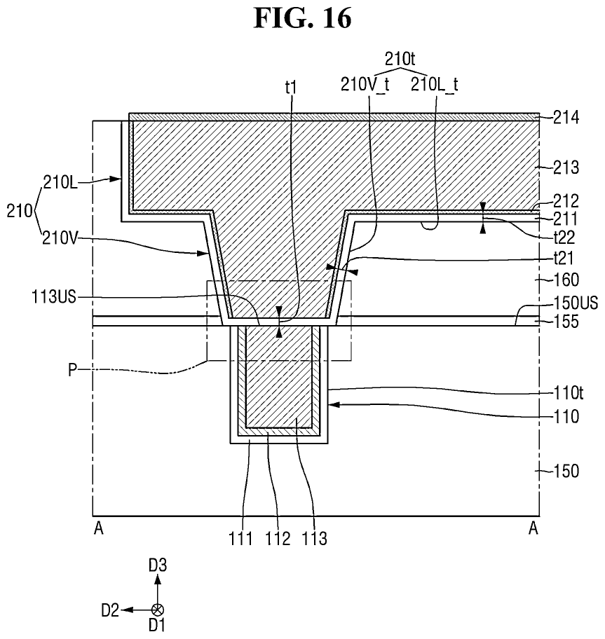

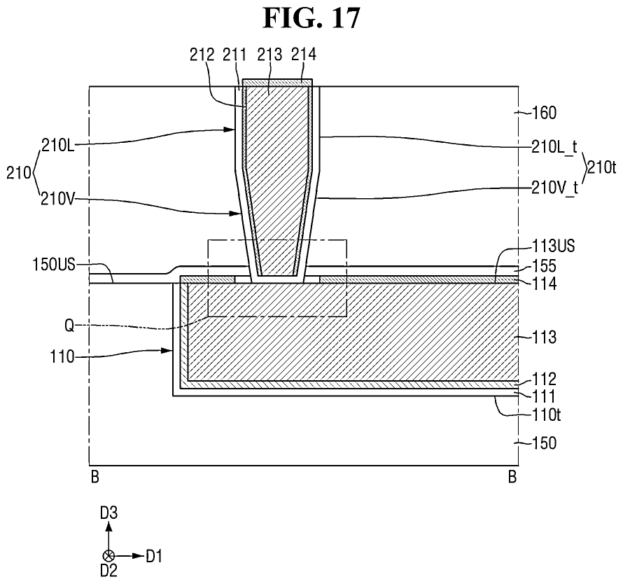

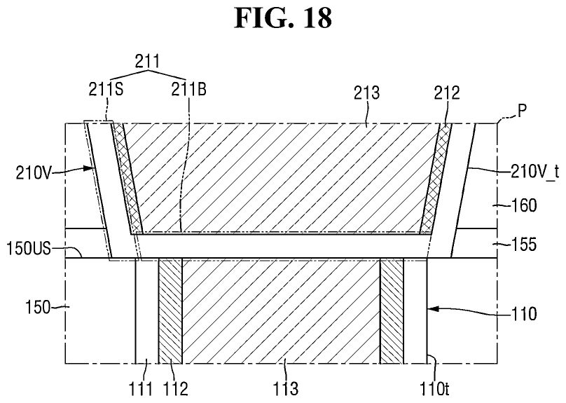

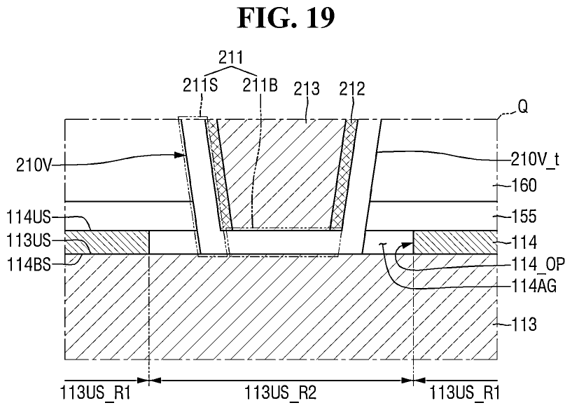

FIG. 16 to FIG. 19 are diagrams for illustrating a semiconductor device according to some embodiments. For convenience of description, differences thereof from what have been described above with reference to FIG. 1 to FIG. 6 will be described. For reference, FIG. 18 is an enlarged view of a P portion of FIG. 16. FIG. 19 is an enlarged view of a Q portion of FIG. 17. Referring to FIG. 16 to FIG. 19, in a semiconductor device according to some embodiments, the upper wiring structure 210 may further include an upper liner 212 disposed between the upper barrier film 211 and the upper filling film 213.

The upper liner 212 may extend along the sidewall of the upper wiring trench 210t. The upper liner 212 may not extend along the lower surface of the upper wiring trench 210t. The upper liner 212 may extend along the sidewall and the lower surface of the upper wiring line trench 210L_t and the sidewall of the upper via trench 210V_t. The upper liner 212 may not extend along the lower surface of the upper via trench 210V_t. The upper liner 212 may contact the upper barrier film 211 and the upper filling film 213. The upper liner 212 may include, for example, manganese (Mn). In one example, the upper liner 212 may include manganese oxide. The upper liner 212 may include a manganese oxide film. In another example, the upper liner 212 may include a manganese film made of manganese. The upper barrier film 211 may include tantalum nitride (TaN).

In one example, the upper barrier film 211 may not contain manganese. Manganese may not be doped in the upper barrier film 211. Each of the sidewall portion 211S of the upper barrier film and the bottom portion 211B of the upper barrier film may not contain doped ruthenium (Ru). For example, each of the sidewall portion 211S of the upper barrier film and the bottom portion 211B of the upper barrier film may be made of tantalum nitride (TaN).

The sidewall portion 211S of the upper barrier film may contain doped ruthenium (Ru). The sidewall portion 211S of the upper barrier film may include ruthenium-doped tantalum nitride (TaN). The bottom portion 211B of the upper barrier film may not contain doped ruthenium (Ru). For example, the sidewall portion 211S of the upper barrier film may be made of tantalum nitride (TaN) doped with ruthenium (Ru). The bottom portion 211B of the upper barrier film may be made of tantalum nitride (TaN) that does not contain ruthenium (Ru).

Each of the sidewall portion 211S of the upper barrier film and the bottom portion 211B of the upper barrier film may contain doped ruthenium (Ru). Each of the sidewall portion 211S of the upper barrier film and the bottom portion 211B of the upper barrier film may include ruthenium-doped tantalum nitride (TaN). For example, each of the sidewall portion 211S of the upper barrier film and the bottom portion 211B of the upper barrier film may be made of tantalum nitride (TaN) doped with ruthenium (Ru).

In another example, the upper barrier film 211 may contain manganese. A portion of the upper barrier film 211 may contain doped manganese. The sidewall portion 211S of the upper barrier film may include tantalum nitride (TaN) doped with manganese. The bottom portion 211B of the upper barrier film may include tantalum nitride (TaN). The bottom portion 211B of the upper barrier film may not contain manganese (Mn).

When the upper barrier film 211 contains manganese, whether each of the sidewall portion 211S of the upper barrier film and the bottom portion 211B of the upper barrier film contains doped ruthenium (Ru) may be substantially the same as described using FIG. 6.

The thickness t21 and t22 of the sidewall portion 211S of the upper barrier film may be equal to the thickness t1 of the bottom portion 211B of the upper barrier film. Unlike what is shown, as described using FIG. 9, the thickness t21 and t22 of the sidewall portion 211S of the upper barrier film may be equal to or greater than the thickness t1 of the bottom portion 211B of the upper barrier film.

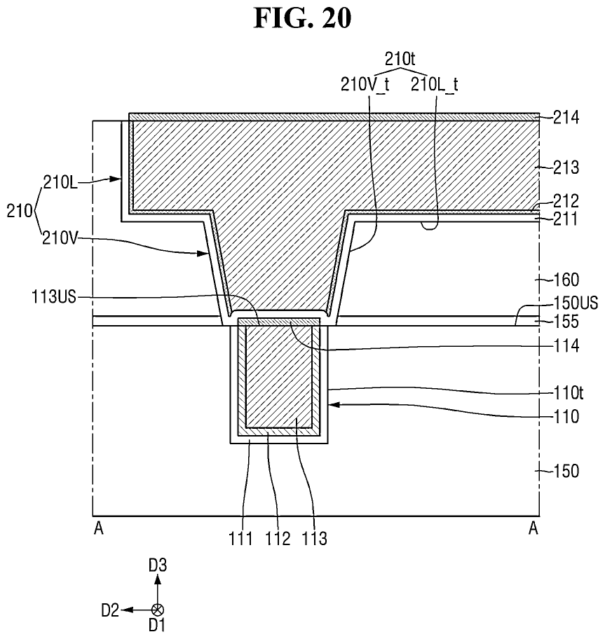

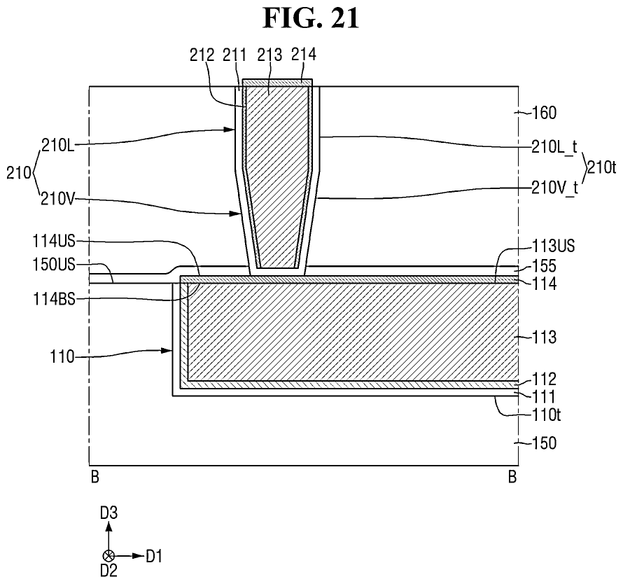

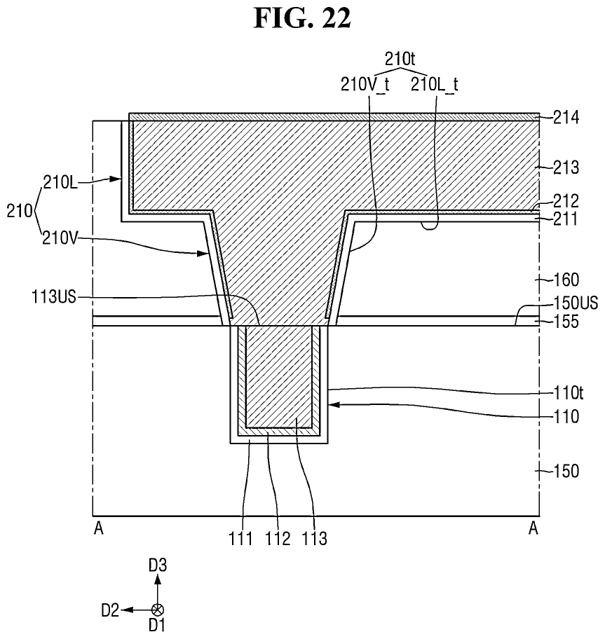

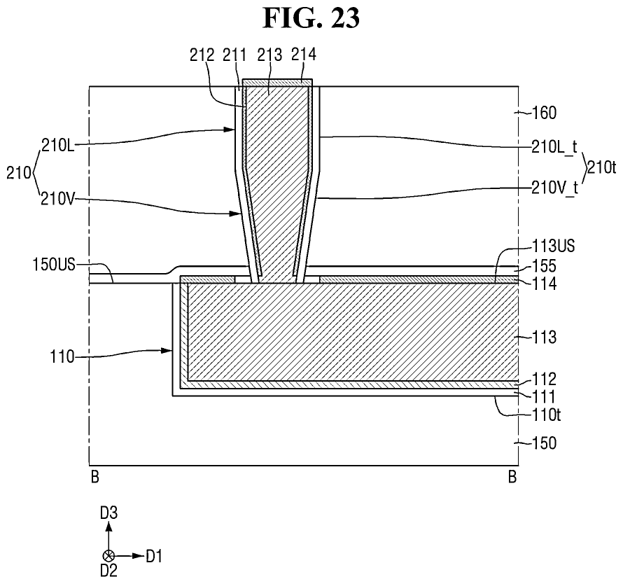

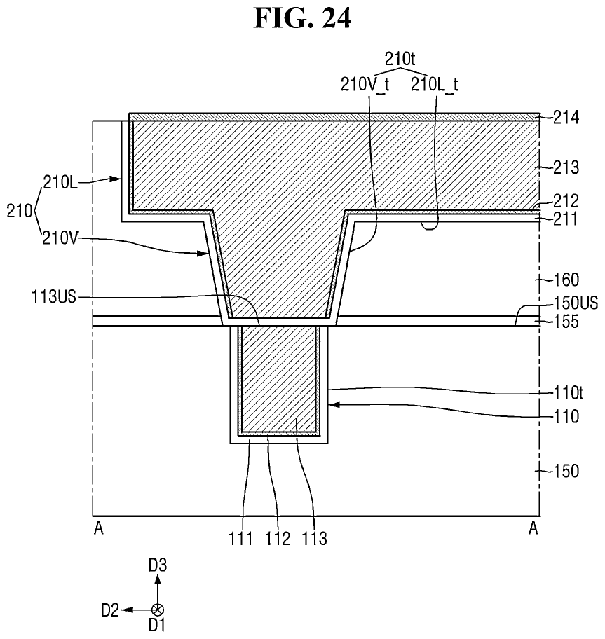

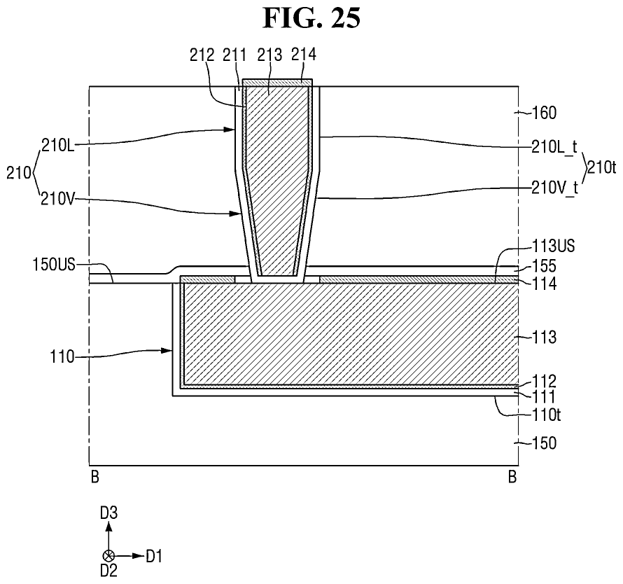

FIG. 20 and FIG. 21 are diagrams for illustrating a semiconductor device according to some embodiments. FIG. 22 and FIG. 23 are diagrams for illustrating a semiconductor device according to some embodiments. FIG. 24 and FIG. 25 are diagrams for illustrating a semiconductor device according to some embodiments. For convenience of description, differences thereof from what have been described above with reference to FIG. 16 to FIG. 19 will be described.

Referring to FIG. 20 and FIG. 21, in a semiconductor device according to some embodiments, the upper barrier film 211 may include a portion extending along the upper surface 114US of the lower capping film. The upper barrier film 211 may contact the upper surface 114US of the lower capping film. Since a portion of the lower capping film 114 is disposed between the upper barrier film 211 and the lower filling film 113, the upper barrier film 211 may not contact the upper surface 113US of the lower filling film.

Referring to FIG. 22 and FIG. 23, in a semiconductor device according to some embodiments, the upper barrier film 211 may not be disposed between the upper filling film 213 and the lower wiring structure 110. The upper filling film 213 may contact the lower wiring structure 110. For example, the upper filling film 213 may contact the upper surface 113US of the lower filling film. The upper liner 212 may extend along a portion of the sidewall (211S in FIG. 18 and FIG. 19) of the upper barrier film. Unlike what is shown, the upper liner 212 may extend to the upper surface 113US of the lower filling film.

Referring to FIG. 24 and FIG. 25, in a semiconductor device according to some embodiments, the lower liner 112 may include manganese (Mn). In one example, the lower liner 112 may include manganese oxide. The lower liner 112 may include a manganese oxide film. In another example, the lower liner 112 may include a manganese film made of manganese. In one example, the lower barrier film 111 may not contain manganese. Manganese may not be doped in the lower barrier film 111. The lower barrier film 111 may include tantalum nitride (TaN) that is not doped with manganese. In another example, the lower barrier film 111 may include tantalum nitride (TaN) doped with manganese (Mn). In still another example, the lower barrier film 111 may include tantalum nitride (TaN) doped with manganese (Mn) and ruthenium (Ru).

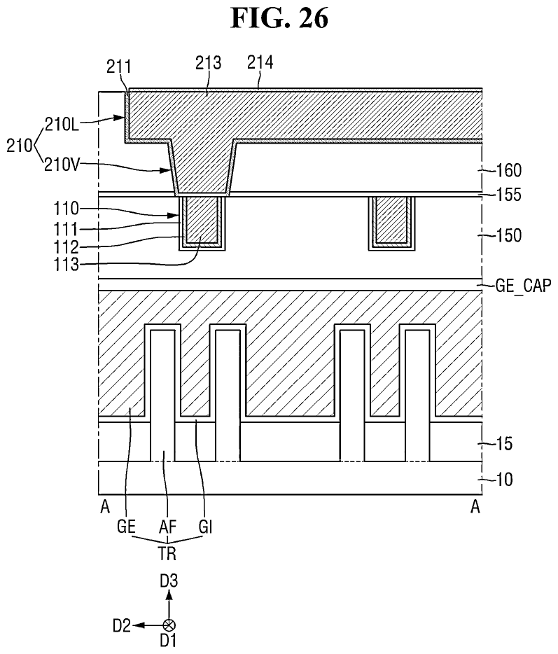

FIG. 26 is a diagram for illustrating a semiconductor device according to some embodiments. For convenience of description, differences thereof from what have been described above with reference to FIG. 1 to FIG. 6 will be described. For reference, FIG. 26 shows an example of a cross-sectional view as cut along a first gate electrode GE. In FIG. 26, a fin-shaped pattern AF is shown as extending in the first direction D1, and the first gate electrode GE is shown as extending in the second direction D2. However, embodiments of the present disclosure are not limited thereto. Referring to FIG. 26, a semiconductor device according to some embodiments may include a transistor TR disposed between a substrate 10 and the lower wiring structure 110.

The substrate 10 may be a silicon substrate or a silicon-on-insulator (SOI). Alternatively, the substrate 10 may include, but is not limited to, silicon germanium, SGOI (silicon germanium on insulator), indium antimonide, lead telluride compound, indium arsenide, indium phosphide, gallium arsenide, or gallium antimonide. The transistor TR may include the fin-shaped pattern AF, the first gate electrode GE on the fin-shaped pattern AF, and a first gate insulating film GI between the fin-shaped pattern AF and the first gate electrode GE.

Although not shown, the transistor TR may include source/drain patterns respectively disposed on both opposing sides of the first gate electrode GE. The fin-shaped pattern AF may protrude from the substrate 10. The fin-shaped pattern AF may extend in an elongate manner in the first direction D1. The fin-shaped pattern AF may be a portion of the substrate 10 or may include an epitaxial layer grown from the substrate 10. The fin-shaped pattern AF may include, for example, silicon or germanium as an elemental semiconductor material. Furthermore, the fin-shaped pattern AF may include a compound semiconductor, for example, a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminun (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

A field insulating film 15 may be formed on a portion of a sidewall of the fin-shaped pattern AF. The fin-shaped pattern AF may protrude upwardly beyond an upper surface of the field insulating film 15. The field insulating film 15 may include, for example, an oxide film, a nitride film, an oxynitride film, or a combination thereof.

The first gate electrode GE may be disposed on the fin-shaped pattern AF. The first gate electrode GE may extend in the second direction D2. The first gate electrode GE may intersect the fin-shaped pattern AF.

The first gate electrode GE may include at least one of, for example, a metal, a conductive metal nitride, a conductive metal carbonitride, a conductive metal carbide, a metal silicide, a doped semiconductor material, a conductive metal oxynitride, and a conductive metal oxide. The first gate insulating film GI may be disposed between the first gate electrode GE and the fin-shaped pattern AF and between the first gate electrode GE and the field insulating film 15. The first gate insulating film GI may include, for example, silicon oxide, silicon oxynitride, silicon nitride, or a high dielectric constant material with a higher dielectric constant than that of silicon oxide. The high dielectric constant material may include, for example, at least one of boron nitride, metal oxide, and metal silicon oxide.

The semiconductor device according to some embodiments may include an NC (negative capacitance) FET using a negative capacitor. For example, the first gate insulating film GI may include a ferroelectric material film having ferroelectric properties and a paraelectric material film having paraelectric properties. The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this regard, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminun (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminun (Al), and yttrium (Y).

When the dopant is aluminun (Al), the ferroelectric material film may contain about 3 to about 8 at % (atomic %) of aluminum. In this regard, a content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide. However, embodiments of the present disclosure are not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, embodiments of the present disclosure are not limited thereto. Because a critical thickness exhibiting the ferroelectric properties may be vary based on a type of the ferroelectric material, the thickness of the ferroelectric material film may vary depending on the type of the ferroelectric material.

In one example, the first gate insulating film GI may include one ferroelectric material film. In another example, the first gate insulating film GI may include a plurality of ferroelectric material films spaced apart from each other. The first gate insulating film GI may have a stack structure in which a plurality of ferroelectric material films and a plurality of paraelectric material films are alternately stacked with each other.

A gate capping pattern GE_CAP may be disposed on the first gate electrode GE. The lower wiring structure 110 may be disposed on the first gate electrode GE. The lower wiring structure 110 is shown as being not connected to the first gate electrode GE. However, embodiments of the present disclosure are not limited thereto.

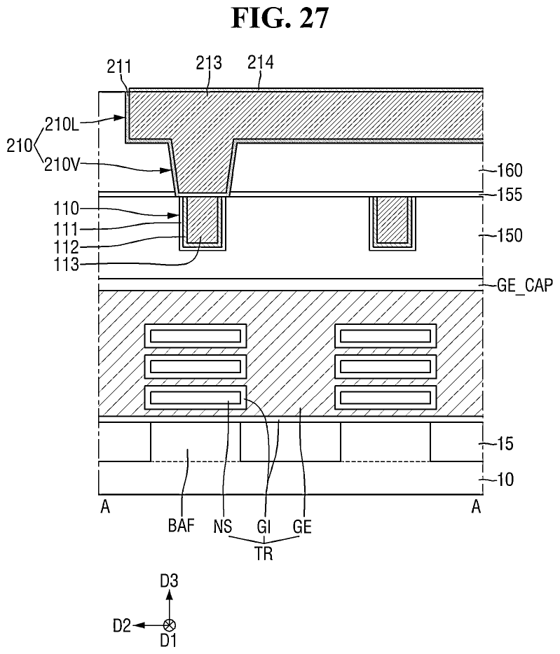

FIG. 27 is a diagram for illustrating a semiconductor device according to some embodiments. For convenience of description, following descriptions are mainly based on differences thereof from the descriptions set forth above using FIG. 26. Referring to FIG. 27, in a semiconductor device according to some embodiments, the transistor TR may include a nanosheet NS, the first gate electrode GE surrounding the nanosheet NS, and the first gate insulating film GI between the first gate electrodes GE and the nanosheet NS.

The nanosheet NS may be disposed on a lower fin-shaped pattern BAF. The nanosheet NS may be spaced apart from the lower fin-shaped pattern BAF in the third direction D3. The transistor TR is shown as including three nanosheets NS spaced apart from each other in the third direction D3. However, embodiments of the present disclosure are not limited thereto. In another example, the number of nanosheets NS arranged in the third direction D3 and disposed on the lower fin-shaped pattern BAF may be larger than 3 or smaller than 3.

Each of the lower fin-shaped pattern BAF and the nanosheet NS may include, for example, silicon or germanium as an elemental semiconductor material. Each of the lower fin-shaped pattern BAF and the nanosheet NS may include a compound semiconductor, for example, a group IV-IV compound semiconductor or a group III-V compound semiconductor. The lower fin-shaped pattern BAF and the nanosheet NS may include the same material or may include different materials.

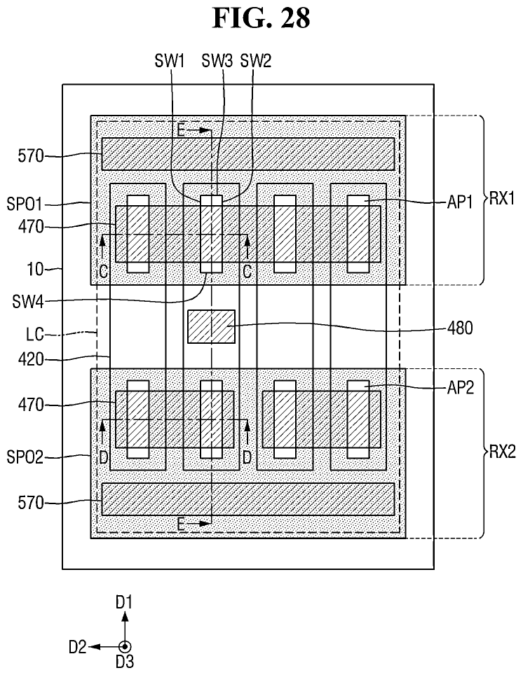

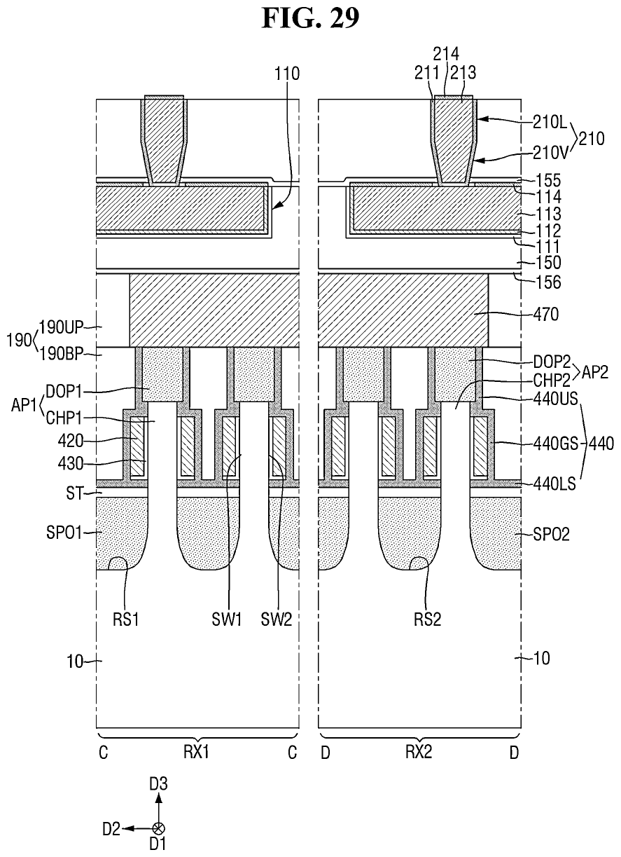

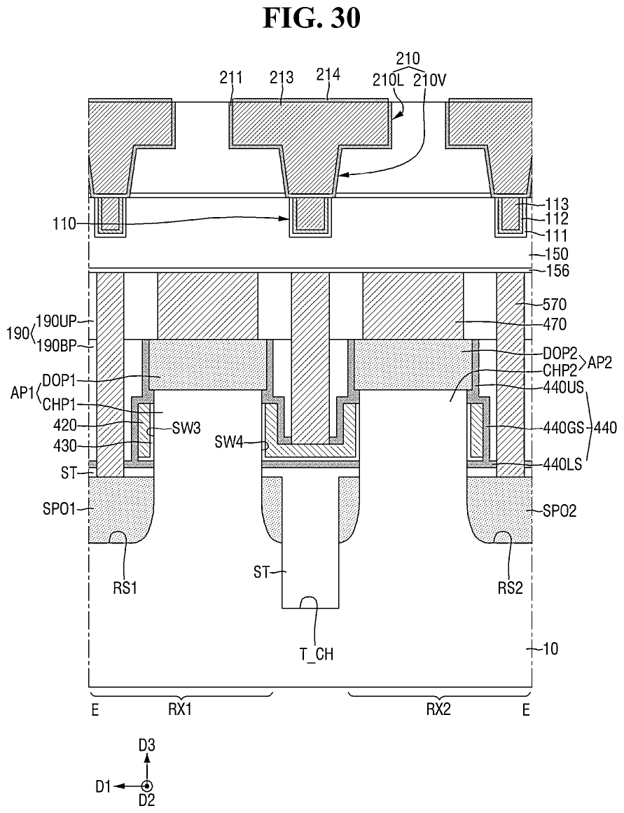

FIG. 28 to FIG. 30 are diagrams for illustrating a semiconductor device according to some embodiments. For reference, FIG. 28 is a plan view for illustrating a semiconductor device according to some embodiments. FIG. 29 is a cross-sectional view cut along lines C-C and D-D in FIG. 28. FIG. 30 is a cross-sectional view cut along a line E-E of FIG. 28. Referring to FIG. 28 to FIG. 30, a logic cell LC may be disposed on the substrate 10. The logic cell LC may refer to a logic element (e.g., an inverter, a flip-flop, etc.) that performs a specific function. The logic cell LC may include vertical transistors (Vertical FETs) constituting a logic element and wirings connecting the vertical transistors to each other.

The logic cell LC on the substrate 10 may include a first active area RX1 and a second active area RX2. For example, the first active area RX1 may be a PMOSFET area, and the second active area RX2 may be an NMOSFET area. The first and second active areas RX1 and RX2 may be defined by a trench T_CH defined in an upper portion of the substrate 10. The first and second active areas RX1 and RX2 may be spaced apart from each other in the first direction D1.

A first lower epitaxial pattern SPO1 may be disposed on the first active area RX1, and a second lower epitaxial pattern SPO2 may be disposed on the second active area RX2. In a plan view, the first lower epitaxial pattern SPO1 may overlap with the first active area RX1, and the second lower epitaxial pattern SPO2 may overlap with the second active area RX2. The first and second lower epitaxial patterns SPO1 and SPO2 may be epitaxial patterns formed by a selective epitaxial growth process. The first lower epitaxial pattern SPO1 may be disposed within a first recess area RS1 of the substrate 10, and the second lower epitaxial pattern SPO2 may be disposed within a second recess area RS2 of the substrate 10.

First activation patterns AP1 may be disposed on the first active area RX1, and second activation patterns AP2 may be disposed on the second active area RX2. Each of the first and second active patterns AP1 and AP2 may have a vertically protruding fin shape. In a plan view, each of the first and second activation patterns AP1 and AP2 may have a bar shape extending in the first direction D2. The first activation patterns AP1 may be arranged along the second direction D2, and the second activation patterns AP2 may be arranged along the second direction D2.

Each of the first active patterns AP1 may include a first channel pattern CHP1 protruding vertically from the first lower epitaxial pattern SPO1 and a first upper epitaxial pattern DOP1 on the first channel pattern CHP1. Each of the second active patterns AP2 may include a second channel pattern CHP2 protruding vertically from the second lower epitaxial pattern SPO2 and a second upper epitaxial pattern DOP2 on the second channel pattern CHP2.

An element isolation film ST may be disposed on the substrate 10 so as to fill the trench T_CH. The element isolation film ST may cover upper surfaces of the first and second lower epitaxial patterns SPO1 and SPO2. The first and second active patterns AP1 and AP2 may protrude upwardly beyond the element isolation film ST. On the element isolation film ST, a plurality of second gate electrodes 420 extending in a parallel manner to each other and in the first direction D1 may be provided. The second gate electrodes 420 may be arranged along the second direction D2. The second gate electrode 420 may surround the first channel pattern CHP1 of the first active pattern AP1 and the second channel pattern CHP2 of the second active pattern AP2. For example, the first channel pattern CHP1 of the first activation pattern AP1 may have first to fourth sidewalls SW1 to SW4. The first and second sidewalls SW1 and SW2 may be opposite to each other in the second direction D2, and the third and fourth sidewalls SW3 and SW4 may be opposite to each other in the first direction D1. The second gate electrode 420 may be disposed on the first to fourth sidewalls SW1 to SW4. In other words, the second gate electrode 420 may surround the first to fourth sidewalls SW1 to SW4.

A second gate insulating film 430 may be interposed between the second gate electrode 420 and each of the first and second channel patterns CHP1 and CHP2. The second gate insulating film 430 may cover a lower surface of the second gate electrode 420 and an inner wall of the second gate electrode 420. For example, the second gate insulating film 430 may directly cover the first to fourth sidewalls SW1 to SW4 of the first active pattern AP1.

The first and second upper epitaxial patterns DOP1 and DOP2 may protrude upwardly beyond the second gate electrode 420. A vertical level of an upper surface of the second gate electrode 420 may be lower than that of a lower surface of each of the first and second upper epitaxial patterns DOP1 and DOP2. In other words, each of the first and second active patterns AP1 and AP2 may protrudes vertically from the substrate 10 and extend through the second gate electrode 420.

The semiconductor device according to some embodiments may include vertical transistors in which carriers migrate in the third direction D3. For example, when a voltage is applied to the second gate electrode 420 such that the transistor is turned “on,” the carriers may migrate from the lower epitaxial patterns SOP1 and SOP2 through the channel pattern CHP1 and CHP2 to the upper epitaxial patterns DOP1 DOP2. In the semiconductor device according to some embodiments, the second gate electrode 420 may entirely surround the side walls SW1 to SW4 of the channel patterns CHP1 and CHP2. The transistor according to the present disclosure may be embodied as a three-dimensional field effect transistor (e.g., VFET) with a gate all around structure. Because the gate surrounds the channel, the semiconductor device according to some embodiments may have excellent electrical characteristics.

On the element isolation film ST, a spacer 440 may be disposed so as to cover the second gate electrodes 420 and the first and second active patterns AP1 and AP2. The spacer 440 may include a silicon nitride film or a silicon oxynitride film. The spacer 440 may include a lower spacer 440LS, an upper spacer 440US, and a gate spacer 440GS between the lower and upper spacers 440LS and 440US.

The lower spacer 440LS may directly cover the upper surface of the element isolation film ST. The second gate electrodes 420 may be spaced apart from the element isolation film ST in the third direction D3 by the lower spacer 440LS. The gate spacer 440GS may cover an upper surface and an outer wall of each of the second gate electrodes 420. The upper spacer 440 may cover the first and second upper epitaxial patterns DOP1 and DOP2. However, the upper spacer 440US may not cover the upper surfaces of the first and second upper epitaxial patterns DOP1 and DOP2 such that the upper surfaces of the first and second upper epitaxial patterns DOP1 and DOP2 are exposed.

A first portion 190BP of the lower interlayer insulating film may be disposed on the spacer 440. An upper surface of the first portion 190BP of the lower interlayer insulating film may be substantially coplanar with the upper surfaces of the first and second upper epitaxial patterns DOP1 and DOP2. A second portion 190UP of the lower interlayer insulating film, and the first and second interlayer insulating films 150 and 160 may be sequentially stacked on the first portion 190BP of the lower interlayer insulating film. The first portion 190BP of the lower interlayer insulating film and the second portion 190UP of the lower interlayer insulating film may be included in the lower interlayer insulating film 190. The second portion 190UP of the lower interlayer insulating film may cover the upper surfaces of the first and second upper epitaxial patterns DOP1 and DOP2.

At least one first source/drain contact 470 extending through the second portion 190UP of the lower interlayer insulating film so as to contact the first and second upper epitaxial patterns DOP1 and DOP2 may be provided. At least one second source/drain contact 570 sequentially extending through the lower interlayer insulating film 190, the lower spacer 440LS, and the element isolation film ST so as to contact the first and second lower epitaxial patterns SPO1 and SPO2 may be provided. A gate contact 480 sequentially extending through the second portion 190UP of the lower interlayer insulating film, the first portion 190BP of the lower interlayer insulating film, and the gate spacer 440GS so as to contact the second gate electrode 420 may be provided.

Between the second portion 190UP of the lower interlayer insulating film and the first interlayer insulating film 150, a second etch stop film 156 may be additionally disposed. The first etch stop film 155 may be disposed between the first interlayer insulating film 150 and the second interlayer insulating film 160.

The lower wiring structure 110 may be disposed within the first interlayer insulating film 150. The upper wiring structure 210 may be disposed within the second interlayer insulating film 160. The detailed descriptions of the lower wiring structure 110 and the upper wiring structure 210 may be substantially the same as the descriptions set forth above using FIG. 1 to FIG. 25.

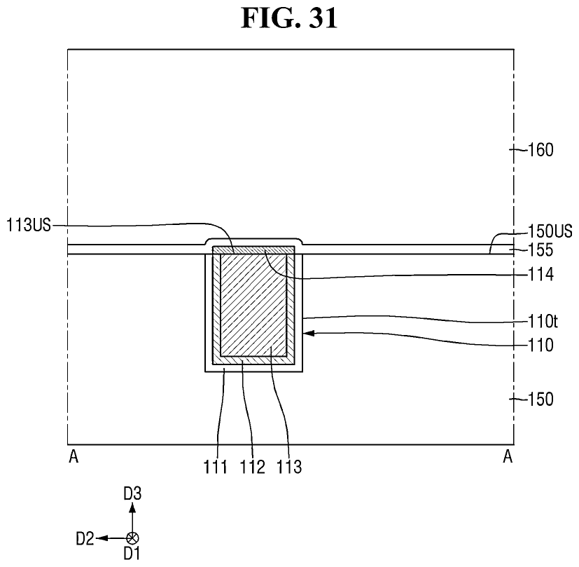

FIG. 31 to FIG. 36 are diagrams of intermediate structures corresponding to intermediate steps for illustrating a method for manufacturing a semiconductor device according to some embodiments. Referring to FIG. 31, within the first interlayer insulating film 150, the lower wiring structure 110 is formed. The lower wiring trench 110t is formed within the first interlayer insulating film 150. Within the lower wiring trench 110t, the lower wiring structure 110 is formed. The lower wiring structure 110 may include the lower barrier film 111, the lower liner 112, the lower filling film 113, and the lower capping film 114. Subsequently, the first etch stop film 155 may be formed on the first interlayer insulating film 150 and the lower wiring structure 110. On the first etch stop film 155, the second interlayer insulating film 160 may be formed.

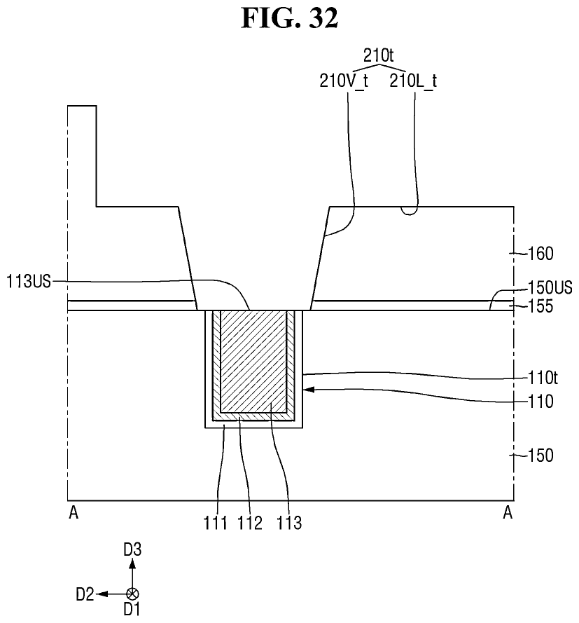

Referring to FIG. 32, the upper wiring trench 210t may be formed within the second interlayer insulating film 160. The second interlayer insulating film 160 may include the upper wiring trench 210t. The upper wiring trench 210t includes the upper via trench 210V_t and the upper wiring line trench 210L_t. The upper wiring trench 210t may extend through the first etch stop film 155. After the first etch stop film 155 has been removed, an exposed portion of the lower capping film 114 may be removed. A portion of the lower capping film 114 disposed between the first etch stop film 155 and the lower filling film 113 may be removed. Although not shown, the lower capping film 114 may be partially undercut under the first etch stop film 155. The upper wiring trench 210t may expose a portion of the upper surface 113US of the lower filling film. Unlike what is shown, while the upper wiring trench 210t is formed, the lower capping film 114 may not be removed.

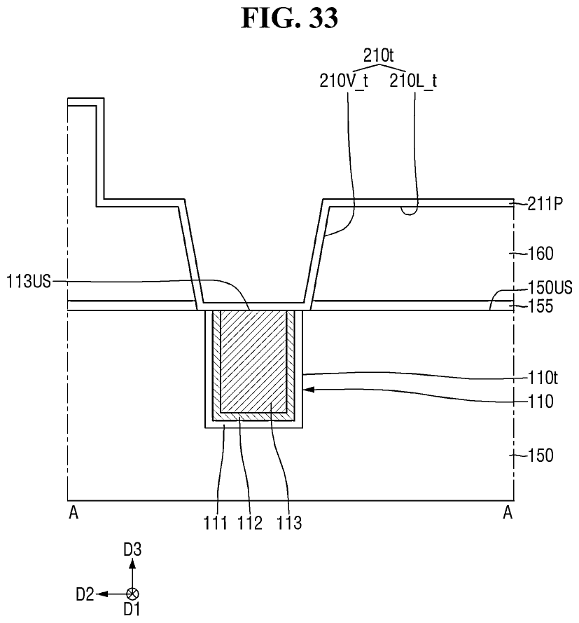

Referring to FIG. 33, a pre-upper barrier film 211P may be formed along the sidewall and the lower surface of the upper wiring trench 210t. The pre-upper barrier film 211P may be formed along the upper surface of the second interlayer insulating film 160. In one example, the pre-upper barrier film 211P may be formed using atomic layer deposition (ALD).

In another example, a portion of the pre-upper barrier film 211P may be formed using atomic layer deposition. A portion of the pre-upper barrier film 211P may be formed along the sidewall and the lower surface of the upper wiring trench 210t. Thereafter, the remainder of the pre-upper barrier film 211P may be formed on a portion of the pre-upper barrier film 211P using physical vapor deposition (PVF).

The pre-upper barrier film 211P is shown as a single film. However, this is only for convenience of illustration and embodiments of the present disclosure are not limited thereto. In one example, the pre-upper barrier film 211P may include a tantalum nitride film. In another example, the pre-upper barrier film 211P may be formed as a stack of multi-films in which a first tantalum nitride film, a ruthenium film, and a second tantalum nitride film are sequentially stacked. During the manufacturing process, ruthenium (Ru) included in the ruthenium film may diffuse into the tantalum nitride film, thereby forming ruthenium (Ru)-doped tantalum nitride (TaN).

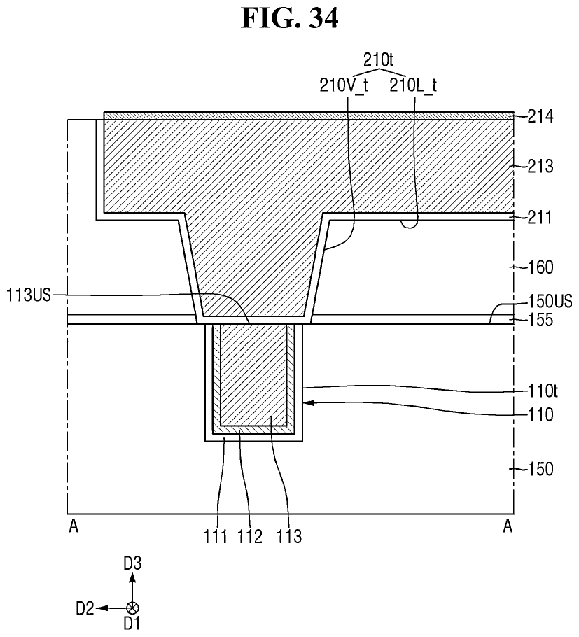

Referring to FIG. 33 and FIG. 34, a pre-upper filling film may be formed on the pre-lower barrier film 211P. For example, the pre-upper filling film may include manganese-doped copper. The pre-upper filling film may be formed using, for example, a plating scheme. However, embodiments of the present disclosure are not limited thereto. The pre-upper filling film may be formed on an upper surface of the second interlayer insulating film 160. The pre-upper barrier film 211P disposed on the upper surface of the second interlayer insulating film 160, and the pre-upper filling film disposed on the pre-lower barrier film 211P may be partially removed. Thus, the upper barrier film 211 and the upper filling film 213 may be formed within the upper wiring trench 210t. The upper filling film 213 may include copper doped with manganese. Subsequently, the upper capping film 214 may be formed on the upper surface of the upper filling film 213. The upper capping film 214 may extend along the upper surface of the upper filling film 213. Thus, the upper wiring structure 210 including the upper wiring line 210L and the upper via 210V may be formed within the upper wiring trench 210t.

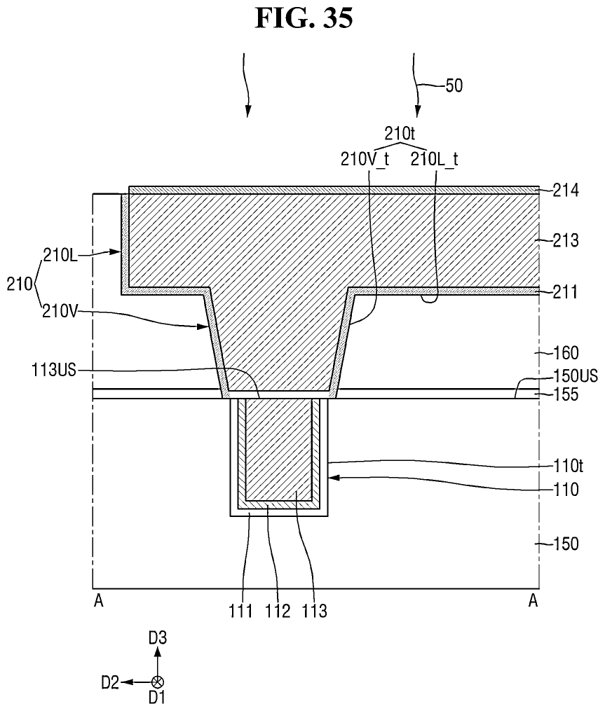

Referring to FIGS. 34 to 36, a heat treatment process 50 may proceed. Thus, the upper wiring structure 210 may be heat-treated. In one example, in FIG. 35, while the heat treatment process 50 is in progress, manganese (Mn) included in the upper filling film 213 may diffuse into the upper barrier film 211 extending along the sidewall of the upper wiring trench 210t. Manganese (Mn) included in the upper filling film 213 may not diffuse into the upper barrier film 211 extending along the lower surface of the upper wiring trench 210t. Manganese (Mn) included in the upper filling film 213 may diffuse toward the second interlayer insulating film 160. Manganese (Mn) included in the upper filling film 213 diffuses into the upper barrier film 211, such that the upper barrier film 211 may include tantalum nitride (TaN) doped with manganese (Mn).

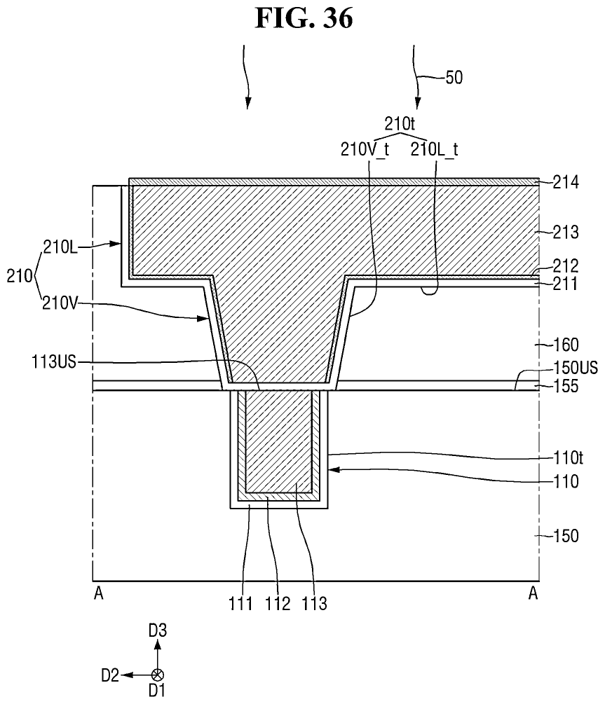

In another example, in FIG. 36, while the heat treatment process 50 is in progress, the upper liner 212 may be formed. The upper liner 212 may be formed by diffusing manganese (Mn) included in the upper filling film 213 toward the upper barrier film 211. The upper liner 212 may be formed at a boundary of the upper barrier film 211 and the upper filling film 213. Unlike what is shown, while the heat treatment process 50 is in progress, the lower barrier film (111 in FIGS. 14 and 15) including manganese-doped tantalum nitride (TaN) may be formed. Alternatively, while the heat treatment process 50 is in progress, the lower liner (112 in FIG. 24 and FIG. 25) including manganese may be formed.

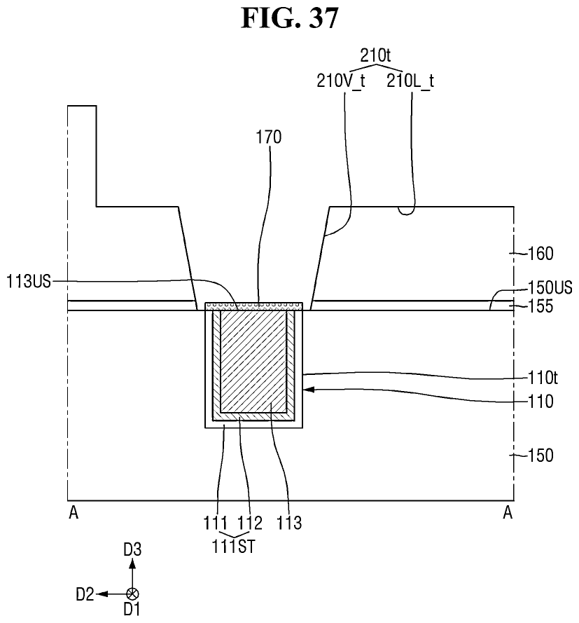

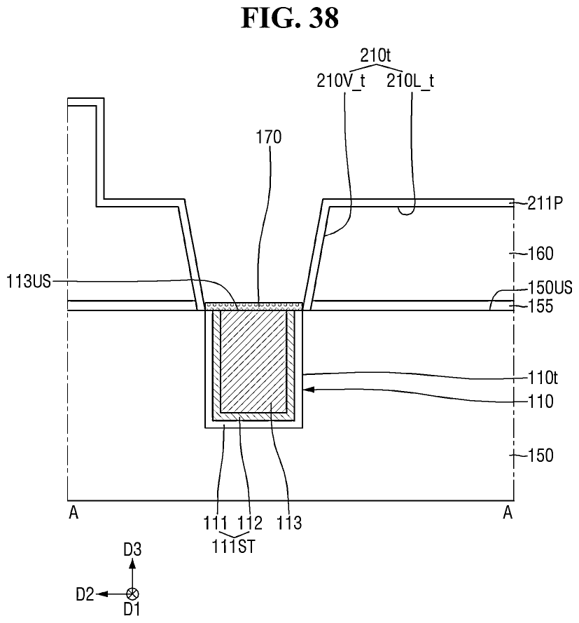

FIG. 37 and FIG. 38 are diagrams of intermediate structures corresponding to intermediate steps for illustrating a method for manufacturing a semiconductor device according to some embodiments. FIG. 37 may be a process after FIG. 32. Referring to FIG. 37, a selective suppressing film 170 is formed on a portion of the lower wiring structure 110 exposed through the upper wiring trench 210t. The selective suppressing film 170 may be formed on a conductive material. The first selective suppressing film 170 is not formed on the insulating material.

The selective suppressing film 170 may be formed on the upper surface 113US of the lower filling film, the upper surface of the lower liner 112, and the upper surface of the lower barrier film 111. Unlike what is shown, the selective suppressing film 170 may not be formed on the upper surface of the lower barrier film 111 and/or the upper surface of the lower liner 112. The selective suppressing film 170 includes an organic material. The selective suppressing film 170 may prevent the conductive material from being deposited on a surface on which the selective suppressing film 170 has been formed.

Referring to FIG. 37 and FIG. 38, in a state in which the selective suppressing film 170 has been formed, the pre-lower barrier film 211P may be formed along the sidewall of the upper wiring trench 210t. The pre-lower barrier film 211P may be formed along the upper surface of the second interlayer insulating film 160. The pre-lower barrier film 211P is not formed on a portion of the lower wiring structure 110 on which the selective suppressing film 170 has been formed. The pre-lower barrier film 211P may not be formed along the lower surface of the upper wiring trench 210t. The pre-lower barrier film 211P may be formed on an entirety of the sidewall of the upper wiring trench 210t.

Unlike what is shown, the pre-lower barrier film 211P may include a stack of multi-films. In this case, the ruthenium film and the second tantalum nitride film among the films included in the pre-lower barrier film 211P may be formed along the lower surface of the upper wiring trench 210t. The first tantalum nitride film which is first formed among the films is not formed along the lower surface of the upper wiring trench 210t.

Subsequently, the selective suppressing film 170 may be removed, thereby exposing the lower wiring structure 110. The selective suppressing film 170 may be removed through, for example, plasma processing. However, embodiments of the present disclosure are not limited thereto. After removing the selective suppressing film 170, a manufacturing process as described using FIG. 34 to FIG. 36 may be performed.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device, comprising:
a lower wiring structure, which includes a lower barrier film and a lower filling film and disposed within a lower interlayer insulating film;
an upper interlayer insulating film disposed on the lower interlayer insulating film, said upper interlayer insulating film having an upper wiring trench therein; and
an upper wiring structure that disposed within the upper wiring trench and is electrically connected to the lower wiring structure, said upper wiring structure including an upper barrier film, an upper filling film, and an upper capping film disposed on the upper filling film;
wherein the upper filling film is disposed on the upper barrier film and is in contact with the upper barrier film;
wherein the upper barrier film includes a sidewall portion extending along a sidewall of the upper wiring trench; and
wherein the sidewall portion of the upper barrier film includes tantalum nitride doped with manganese (Mn).

2. The semiconductor device of claim 1, wherein the upper barrier film further includes a bottom portion, which is made of tantalum nitride and extends along a lower surface of the upper wiring trench.

3. The semiconductor device of claim 2, wherein a thickness of the sidewall portion of the upper barrier film is equal to or greater than a thickness of the bottom portion of the upper barrier film.

4. The semiconductor device of claim 1, wherein the sidewall portion of the upper barrier film further contains ruthenium (Ru) as a dopant.

5. The semiconductor device of claim 4, wherein the upper barrier film further includes a bottom portion, which is made of tantalum nitride and extends along a lower surface of the upper wiring trench.

6. The semiconductor device of claim 4, wherein the upper barrier film further includes a bottom portion, which is made of ruthenium-doped tantalum nitride and extends along a lower surface of the upper wiring trench.

7. The semiconductor device of claim 1, wherein the upper filling film is in contact with the lower wiring structure.

8. The semiconductor device of claim 1, wherein the lower barrier film includes manganese-doped tantalum nitride, and is in contact with the lower filling film.

9. The semiconductor device of claim 1, wherein the lower wiring structure further includes a lower liner disposed between the lower barrier film and the lower filling film; wherein the lower barrier film includes manganese (Mn); and wherein the lower liner includes cobalt (Co).

10. A semiconductor device, comprising:
a lower wiring structure, which includes a lower barrier film and a lower filling film and disposed within a lower interlayer insulating film;
an upper interlayer insulating film disposed on the lower interlayer insulating film, said upper interlayer insulating film having an upper wiring trench therein; and
an upper wiring structure disposed within the upper wiring trench and is electrically connected to the lower wiring structure, said upper wiring structure including an upper barrier film, an upper filling film, and an upper liner extending between the upper barrier film and the upper filling film;
wherein the upper barrier film includes tantalum nitride;
wherein the upper liner includes manganese (Mn), and extends along a sidewall of the upper wiring trench but not along a lower surface of the upper wiring trench.

11. The semiconductor device of claim 10, wherein the upper barrier film includes a sidewall portion extending along a sidewall of the upper wiring trench, and a bottom portion extending along a lower surface of the upper wiring trench.

12. The semiconductor device of claim 11, wherein each of the sidewall portion of the upper barrier film and the bottom portion of the upper barrier film is made of tantalum nitride.

13. The semiconductor device of claim 11, wherein the sidewall portion of the upper barrier film is made of tantalum nitride doped with ruthenium (Ru), but the bottom portion of the upper barrier film is made of tantalum nitride that is free of ruthenium.

14. The semiconductor device of claim 11, wherein each of the sidewall portion of the upper barrier film and the bottom portion of the upper barrier film is made of ruthenium-doped tantalum nitride.

15. The semiconductor device of claim 11, wherein a thickness of the sidewall portion of the upper barrier film is equal to or greater than a thickness of the bottom portion of the upper barrier film.

16. The semiconductor device of claim 11, wherein the lower wiring structure further includes a lower capping film in contact with an upper surface of the lower filling film; and wherein the upper barrier film is in contact with the upper surface of the lower filling film.

17. The semiconductor device of claim 10, wherein the upper barrier film extends along a sidewall of the upper wiring trench, but does not extend along a lower surface of the upper wiring trench; and wherein the upper filling film is in contact with an upper surface of the lower filling film.

18. The semiconductor device of claim 10, wherein the upper liner includes manganese oxide.

19. A semiconductor device, comprising:
a lower wiring structure disposed within a lower interlayer insulating film, said lower wiring structure including a lower barrier film, a lower capping film, and a lower filling film in contact with the lower barrier film and the lower capping film;
an upper interlayer insulating film disposed on the lower interlayer insulating film and includes an upper wiring trench therein; and
an upper wiring structure disposed within the upper wiring trench and is electrically connected to the lower wiring structure, said upper wiring structure including an upper barrier film, an upper filling film, and an upper capping film disposed on the upper filling film;
wherein the upper filling film is disposed on the upper barrier film and is in contact with the upper barrier film and the upper capping film;
wherein the upper barrier film includes a sidewall portion extending along a sidewall of the upper wiring trench and a bottom portion extending along a lower surface of the upper wiring trench;
wherein each of the sidewall portion of the upper barrier film and the lower barrier film includes tantalum nitride doped with manganese (Mn);
wherein the bottom portion of the upper barrier film includes manganese;
wherein each of the upper capping film and the lower capping film includes cobalt (Co); and
wherein each of the upper filling film and the lower filling film includes copper (Cu).

20. The semiconductor device of claim 19, wherein the sidewall portion of the upper barrier film includes manganese and ruthenium-doped tantalum nitride.
